(19) United States
(12) Patent Application Publication
(10) Pub. No.: US 2026/0247752 A1
(43) Pub. Date: Aug. 20, 2026

(54) OPTOELECTRONIC DEVICE AND METHOD FOR PROCESSING THE SAME

(71) Applicant: ams-OSRAM International GmbH, Regensburg (DE)

(72) Inventors: Jong Ho Na, Regensburg (DE); Bastian Galler, Regensburg (DE); Xiaojun Chen, Penang (MY); Azharul Ariff Kamarulzaman, Regensburg (DE); Noor Afifa Mohd Hanafiah, Regensburg (DE)

(21) Appl. No.: 19/161,648

(22) PCT Filed: Feb. 28, 2024
(86) PCT No.: PCT/EP2024/055075

§ 371 Date: Sep. 2, 2025

(30) Foreign Application Priority Data
Mar. 3, 2023 (DE) 10 2023 105 229.2

(51) Int. Cl. H10H 20/825; H10H 20/01; H10H 20/812

(52) U.S. Cl. CPC H10H 20/825; H10H 20/0133; H10H 20/812

(57) ABSTRACT

In an embodiment a method for manufacturing an optoelectronic device includes depositing a first layer having a first dopant concentration of a first doping type, depositing an active region on the first layer, and depositing a second layer having a second dopant concentration of a second doping type on the active region, wherein depositing the active region includes depositing a plurality of alternating barrier layers including Inₓ(Ga_{y}Al_{1-y})₁₋ₓN and quantum well layer including Inₓ(Ga_{y}Al_{1-y})₁₋ₓN, with x, y as parameters in an interval of [0;1], respectively and x+y=1, wherein an aluminum content in a barrier layer is higher than in a quantum well layer and doping the barrier layers with silicon during deposition of a barrier layer material such that a subset of the plurality of barrier layers has a higher silicon dopant concentration than remaining barrier layers.

### CROSS-REFERENCE TO RELATED APPLICATIONS

This patent application is a national phase filing under section 371 of PCT/EP2024/055075, filed Feb. 28, 2024, which claims the priority of German patent application no. 10 2023 105 229.2, filed Mar. 3, 2023, each of which is incorporated herein by reference in its entirety.

### TECHNICAL FIELD

The present invention concerns a method for processing an optoelectronic device as well as an optoelectronic device.

### BACKGROUND

Optoelectronic devices and in particular μ-LEDs with a size smaller than 50 μm are often using a multi-quantum well structure as active layer for generating photons by charge carrier recombination. Such multi-quantum well structures comprise a plurality of alternating quantum well layers and barrier layers. The difference between quantum well layers and the barrier layers lie in the bandgap, said band gap again depending on the material composition. More particularly, the quantum well layers comprise a smaller bandgap compared to the barrier layers.

In ternary or quaternary semiconductors based on nitride material systems like InGaN or InGaAlN for example, such bandgap differences between the quantum well layers and the barrier layers is achieved by varying the aluminum content between the respective layers. A higher aluminium content usually results in a higher bandgap for the barrier layers, trapping the charge carriers within the quantum well layers.

It has been found that by doping the barrier layer, the operating voltage or forward voltage Vf at a given current can be lowered. For high efficiency InGaN optoelectronic devices, Silicon or Silicon is used as a dopant in the barrier layer (usually the barrier and quantum well layer are undoped). The Silicon doping in the quantum barrier layers leads to a reduced operating voltage Vf and a reduction of the polarization field. Both aspects enhance the optical output power and the efficiency of the device and are often desirable.

However, doping the quantum barrier layers increases the parasitic capacitance in the p-n junction. A high capacitance results in a longer delay in turn-on or turn-off operation, as the charge carriers induce by the dopant have to be compensated. It has been found that the capacitance increases proportionally to not only by Silicon but also by Magnesia, Mg doping, the latter being used for p-doping. Consequently, while an Silicon-doping in the quantum barrier layers is desirable for a lower operating voltage and a higher efficiency in output, the switching speed decreases due to the higher capacitance. Hence, high switching speeds while maintaining a low operating voltage is a desired goal.

### SUMMARY

Embodiments provide to reduce the overall capacitance in μ-LEDs based on III-V optoelectronic devices, thereby increasing the switching speed, without strongly degrading the performance of efficiency.

It has been observed that Silicon doping in the quantum well barrier reduces the forward voltage due to the hole transport blocking effects of the doped quantum barrier layers. While this might by a useful effect for reducing the operating voltage, it has also been observed that the electroluminescence decreases with increasing Silicon doping in quantum barrier layer.

The inventor realized that for operating an optoelectronic device, any charges in the depletion or active region (or being part thereof), that is the plurality of quantum well layers and quantum barrier layers must be removed by pushing free charge carrier into the depletion region. These carriers leave the region when the voltage pushed them vanishes, and then move back to the current-voltage source. This process never results in light generation, but rather corresponds to “turn-on delay” of LED operation. The inventor now aims to reduce this space charge induced by the doping, without degrading the benefits of such doping.

For this purpose, the inventor proposes a revised method for processing a μLED or more generally an optoelectronic device. Although the proposed principle is implemented with regards to optoelectronic devices having an edge length of smaller than 100 μm (generally referred to as μLED) and down to 5 μm or even less, the proposed method is not limited to such small devices. The method comprises depositing a first layer having a first dopant concentration of a first dopant type and a second layer having a silicon dopant concentration of a Silicon dopant type on an active region explained further below in greater detail.

In this regard, the first dopant type corresponds to one of n-dopants or p-dopants and the Silicon dopant type corresponds to one of p-dopants and n-dopants. Non limiting examples of dopant material that provides n-doping in a III-V semiconductor material like GaN, InGaN or InGaAlN include Te, Ge or Si, while a p-doping can be achieved by implanting Sn or Mg. for the purpose of the present application, the expression first dopant type corresponds to an n-doping type, the expression second doping type corresponds to a p-doping type. However, the proposed principle is not limited to this specific definition; rather the dopant type described herein can be exchanged unless otherwise noted.

First and second layers may comprise a constant doping distribution but can also have a plurality of sub-layers with varying dopant concentrations. In some aspects, the first and/or second layer each comprise an undoped sublayer adjacent to the active region between the sublayers. Hence, the sublayer may act a doping diffusion barrier layer to prevent an undesired diffusion of dopant from the first and/or second layer into the active region. Some further sublayers of the first and/or second layer may comprise an increased doping concentration, thereby forming a current distribution and/or current injection layer. In addition, sublayer of the first and/or second layer opposite the active region are configured as contact layers in some aspects of the proposed principle.

As outlined in some aspects, an active region is deposited between the first and second layer. The active layer comprises a multi quantum well structure having a plurality of alternating barrier layers and quantum well layers, respectively. During depositions of the alternating barrier and quantum well layers an aluminum content of the deposited semiconductor material is varied. More particularly, depositing the plurality of alternating barrier layers comprise depositing Inₓ(Ga_{y}Al_{1-y})₁₋ₓN layers, wherein the x and y are parameters in the range of [0:1] and x+y=1. Consequently, some of the Gallium is replaced by aluminum, whereas the amount of replacement can be between 0 and 1, resulting in InₓGa₁₋ₓN (for aluminum content equals zero) and InₓAl₁₋ₓN (for aluminum equals 100% and no Ga present). Usually the aluminum content in the barrier layer is above 0.1 and may be in the range between 0.15 and 0.40 for blue LEDs. Al Contents above 0.4 is more preferable in UV (ultra-violet) LEDs application. Overall the aluminum content in the barrier layers is larger than in the adjacent quantum well layers. This can be achieved by varying the concentration of the precursor with the aluminum during deposition of the active region material.

The increased concentration of aluminum content in the barrier layers increases the bandgap. In accordance with the proposed principle, the barrier layers are doped with Silicon during deposition of the barrier layer material of the plurality of barrier layers. However, said doping is not constant, but results in that a subset of the plurality of barrier layers comprises a higher Silicon dopant concentration than the remaining barrier layers. In other words, the Silicon dopant concentration is varied during deposition of the plurality of barrier layers resulting that some of the deposited barrier layers contain a higher Silicon concentration than the remaining barrier layers.

It has been found that a varying concentration of Silicon with an increased dopant concentration in just some of the barrier layers will result in a reduced forward voltage compared to conventional devices while also reduce the overall capacitance. In other words, the same specific forward voltage for a given Silicon concentration in conventional devices can be achieved with a reduced Silicon concentration in accordance with the proposed principle, namely to vary the concentration in the barrier layers increasing the Silicon concentration in a few barrier layers. The overall Silicon dopant concentration in the barrier layers is reduced compared to conventional devices having the same or very similar forward voltages resulting in a reduced turn-on delay (and thus increased switching time).

In fact, it has been observed that certain configurations of Silicon concentrations in the barrier layers reduce the forward voltage under a reference voltage that is achieved with an equally distributed Silicon configuration across the barrier layers but an overall larger amount of Silicon dopants being deposited within the active region. Consequently, the over amount of Silicon dopant can be reduced while surprisingly maintaining a reduced forward voltage and enabling a higher switching speed for the device.

In this regard, the expression “equally distributed concentration across the barrier layers” refers to a distribution, in which each barrier layer contains approximately the same amount of Silicon dopant, although the dopant may not be equally deposited within each respective barrier layer. Likewise, the expression “average” refers to the overall amount of Silicon dopant across the plurality of barrier layers, but not their distribution among the barrier layers. In accordance with the proposed principle, the distribution of Silicon dopant varies across the barrier layers, with the average Silicon concentration being smaller than in conventional devices and with the forward voltage being the same or similar.

For example, in some instances, the aver Silicon dopant concentration is less than 40% of the reference Silicon dopant concentration and more particularly less than 30%. However, the Silicon dopant distribution is not constant, but a subset of barrier layers are deposited with a higher Silicon concentration than the remaining ones. Hence, the step of doping barrier layers comprises doping the plurality of barrier layers during respective deposition of the barrier layer material, wherein the dopant concentration is increased during deposition of the subset of the plurality of barrier layers.

In some aspects, it has been observed that forward voltage as well as switching time is dependent on the position of the higher Silicon dopant concentration within the active region and position of the subset of the plurality of barrier layers within the active region. In some aspects, the subset of the plurality of barrier layers are subsequent barrier layers. In other words, the barrier layers corresponding to the subset of barrier layers are not distributed along the plurality of barrier layers, but rather form a group of barrier layers, each of them having a higher Silicon concentration compared to the other ones of the plurality of barrier layers.

In some aspects, the subset or the group of barrier layers with higher concentration are closer to one of the first and second layer. In some aspects the group of barrier layers is substantially in the centre of the plurality of barrier layers. It has been found that the forward voltage is generally lower (or at least not substantially increased compared to a reference voltage given by a reference concentration of Silicon dopants) if the subset of barrier layers with higher Silicon concentration is arranged to the one of the p-doped and n-dope side. In some aspects, the subset of barrier layers is adjacent to the n-doped side of the optoelectronic device.

In some other aspects, the barrier layers corresponding to the subset of the plurality of barrier layers are distributed across the active region. In some aspects, the barrier layers corresponding to the subset with higher Silicon concentration are alternating with barriers having a lower concentration. For example, in some aspects, every third barrier layer of the plurality of barrier layers may correspond to the subset of the plurality of barrier layers. It has been found that a higher dopant concentration in the first barrier layer (adjacent to one of the p-doped and n-doped side, respectively with an overall reduced dopant concentration in the remaining barrier layers may result in maintaining the forward voltage compared to a reference concentration. Consequently, in such configuration the overall Silicon concentration compared to a reference concentration can be reduced.

Some aspects concern the amount of barrier layers in the subset of the plurality of barrier layers in comparison to the total amount of barrier layers. In some aspects, the number of barrier layers in the subset of the plurality of barrier layers is approximately 15% to 45% and in particularly between 25% and 35% of the overall number of barrier layers. In some aspect, about ⅓ of the barrier layers (e.g. 3 out of 10) contains an increased Silicon dopant concentration compared to the remaining ones. As mentioned previously, at least one of such barrier layers may be adjacent to one of the p-doped and n-doped side. Generally, the number of barrier layers in the subset of the plurality of barrier layers is smaller than the number of the remaining barrier layers (e.g. not part of the subset).

Some aspects related to an amount the overall Silicon concentration of an optoelectronic device and a method for processing such device in accordance with the proposed principle. In some aspects, the Silicon dopant concentration in the subset of the plurality of barrier layers is larger than 50% of the overall dopant concentration in the plurality of barrier layers. In some aspects, the overall amount of Silicon dopants in the subset of the plurality barrier layers may be in the range between 50% to 80% of the overall amount of Silicon dopant and in particular between 60% and 70%. In some aspects, the dopant concentration in the subset of the plurality of barrier layers is larger than 55% of the overall dopant concentration in the plurality of layers and in particular larger than 60%. Hence, the remaining barrier layers may contain between 35% and 50% of an overall amount of Silicon dopants.

In some instances, the Silicon dopant is therefore concentrated in a small number of barrier layers, e.g. ⅓ of the total number of barrier layers, but the amount of Silicon dopants sums up to about 60% to 75% of the overall amount of deposited Si. In addition, one should note that the overall amount of Silicon dopant in the plurality of barrier layers is already reduced compared to reference amounts in conventional devices. In some instances, the overall amount of Silicon dopants is approximately between 25% and 40% of a reference amount. In other words, and in accordance with the proposed principle, one can achieve approximately the same forward voltage even with an amount of Silicon dopants that is less than half the amount of Silicon dopant previously used.

Some aspects concern the deposition of the dopants during depositing the barrier material. In some aspects, the step of doping barrier layers during deposition of the barrier layer material comprises depositing the dopant material after depositing a portion of the respective barrier layer and/or finishing depositing the dopant material while continuing depositing barrier layer material. Consequently, the Silicon dopants are not equally distributed across a barrier layer. Rather Silicon may be doped into the barrier layer material after some barrier layer material has already been deposited. In some instances, the amount of Silicon doping may vary even during depositing the barrier layer material. For example, in some instances, the Silicon doping may occur only during a time interval shorter than a duration for depositing the barrier layer material, whereas the time interval may start after the depositing the barrier layer material has started and/or may stop prior to stopping depositing the barrier layer material.

In some instances, the distribution of doping in the plurality of barrier layers may be the same, although the concentration of dopants is increased during deposition of the subset of barrier layers. In some other instances, the doping distribution in the subset of the plurality of barrier layers may be different compared to the other ones of the plurality of barrier layers.

In this regard, the step of doping barrier layers with Silicon comprises doping alternate barrier layers with a larger amount of Silicon dopants, in particularly doping every third barrier layer. In some aspects, only every third or fourth barrier layer is doped with a larger amount of Silicon dopants compared to the other barrier layers.

In some aspects, the Silicon dopant concentration within the subset of the plurality of barrier layers is in the range between 2e17 1/cm³ to 5e18 1/cm³. In some aspects, the Silicon concentration in the subset of the plurality of barrier layers does not exceed a concentration of about 1e19 1/cm³.

Given the above ratio of larger than 50% of the overall amount of Silicon as dopant, while only having approximately 33% being higher doped, the average amount of Silicon in the active region may be between 5e16 1/cm³ to 2e18 1/cm³. In some instances, an average dopant concentration within the plurality of barrier layers is in the range between 1e17 1/cm³ and 1e18 1/cm³. In some instances, the amount of Silicon dopant concentration in the barrier layers not being part of the subset is less than 1e18 1/cm³ and particularly less than 5e17 1/cm³. in some aspects, the dopant concentration within the subset of the plurality of barrier layers may be at least twice as large as dopant concentration within the remaining barrier layer not part of the subset.

Apart from the Silicon doping during deposition of the barrier layers of the active region, one may also induce dopants of a different doping type during deposition of the active region layers. In this regard, dopant of a different doping type includes but are not limited to p-dopants, for example Mg. In such case, it is assumed that Silicon as dopant resembles an n-type dopant. Consequently in some aspects, at least portions of the active region are doped with a Silicon dopant of a doping type different than the doping type of Si, for example Mg. in this regard, one may also try to reduce the overall concentration of Mg or distribute the dopant non-uniformly to achieve a reduction of the charge capacitance thus improving the switching speed.

Another aspect is related to an optoelectronic device and particularly to a PLED having a length smaller than 100 μm and particularly smaller than 50 μm. In some aspects, the optoelectronic device comprises a first layer having a first dopant concentration of a first dopant type and a second layer on the active region, said second layer having a Silicon dopant concentration of a Silicon dopant type. An active region is arranged between the first and second layers, respectively. Similar to the above-mentioned method, the first and second layers can comprise a plurality of sublayers including but not limited to current injection or current distribution layers. Some highly doped sub-layers being part of the first and second layer, respectively and may form contact layers for metallic contacts to de deposited thereupon.

In some aspects, each of the first and second layer may comprise an undoped cladding layer adjacent to the active region. The cladding layer can comprise a different material, e.g. with a different bandgap compared to the active region and/or the other sublayers of the first and second layers. They can act as a diffusion barrier layer to prevent an undesired diffusion of dopants from the first or second layer into the active region.

In accordance with the proposed principle, the active region comprises a plurality of alternating barrier layers comprising Inₓ(Ga_{y}Al_{1-y})₁₋ₓN and quantum well layer comprising Inₓ(Ga_{y}Al_{1-y})₁₋ₓN, with x, y as parameters in the interval of [0:1], respectively and x+y=1 and wherein the aluminum content in the barrier layer is higher than in the quantum well layer. Usually, the aluminum content in the barrier layer is above 0.4 and may be in the range between 0.45 and 0.75. A subset of the plurality of barrier layers comprises a higher doping concentration, particularly a higher doping of Silicon than the remaining barrier layers.

Although the dopant levels of Silicon varies within the barrier layers, the overall amount of Silicon dopants is reduced with respect to a reference doping level that results in a certain forward voltage level. Still, even at smaller dopants levels, the forward voltage is maintained at approximately the same level. This is due to the non-uniform across the active region, with some of the barrier layers having a larger concentration of dopants than others. Nevertheless, the reduced overall dopant level reduces the parasitic capacitance of the active region and thus decreases the on-delay significantly.

Consequently, the proposed optoelectronic device resembles the same electrical and optical efficiency with a reduced doping level in the active region and an increased switching speed. In some instances, the subset of the plurality of barrier layers are arranged subsequently to each other. Hence, the barrier layers with the increased doping level follow each other. In addition, the subset of barrier layers may be located adjacent to the first layer, or adjacent to the layer having the same doping type as the subset of barrier layers.

In some alternative aspects, the barrier layers corresponding to the subset of the plurality of barrier layers alternate with barrier layers not corresponding to the subset of the plurality of barrier layers. In this regard, it is possible that there is first an alteration between barrier layers corresponding to the subset of the plurality of barrier layers alternate with barrier layers not corresponding to the subset followed by another number of barrier layers not corresponding to the subset.

In some aspects, the number of barrier layers corresponding to the subset of barrier layers is smaller than the number of barrier layers not corresponding to the subset of barrier layers. In other words, there are more barrier layers with a smaller dopant concentration than barriers with a larger doping concentration, the latter corresponding to the subset. In this regard, one may note that in some aspects, an amount of barrier layers in the subset of the plurality of barrier layers is approximately between 15% to 45% and in particularly between 25% and 35% of the overall amount of the plurality of barrier layers. In other words, there are about 2 to 4 times more barrier layers with a reduced amount of doping than barrier levels with an increased amount of doping.

Some aspects concern a thickness of the barrier layers. In some aspects, a thickness of a barrier layer may be between 5 nm and 80 nm, but usually larger than 10 nm and less than 60 nm. The area within a barrier layer, in which the barrier layer material is doped may however vary and in particularly smaller than the thickness of the barrier layer itself. In other words, the barrier layer may not be completely doped, but rather the dopant may follow a certain distribution across the thickness of the barrier level. In this regard, it is possible that the dopant may diffuse slightly within the barrier layer, such that no clear border can be established.

Still in some aspects, a thickness of a barrier layer of the subset of barrier layers may be larger than a thickness of a doped region within said barrier layer. Consequently, said barrier layer may not be fully doped, but rather the dopant within said barrier layer may follow a doping distribution. In some aspects, the doped region is not adjacent to quantum well layer adjacent to said barrier layer. in other aspect, there is a region of a barrier layer adjacent to a quantum well layer that is doped with Si.

In this regard, it is understood by the skilled person that it is not required for the barrier layer within the subset to have the same dopant concentration either, neither do the barrier layers not corresponding to the subset need to have the same dopant concentration. Hence, one can vary the dopant concentration of the different barrier layer and for example implement three subsets of barrier layers, each of the subsets having a difference dopant concentration.

In some aspects, the dopant concentration in the subset of the plurality of barrier layers is larger than 50% of the overall dopant concentration in the plurality of barrier layers and in particular larger than 55%. Hence, the majority of silicon dopants within the active region is therefore concentration within the subset of the plurality of barrier layers. As the number of barrier layers within the subset is smaller than the number of barrier layers not corresponding to the subset, the majority of silicon dopants are thus concentrated in a small portion of the active region.

In some other aspects, a dopant concentration in a barrier layer of the subset of the plurality of barrier layers varies along the thickness of said barrier layer, in particularly increases towards a quantum well layer adjacent to said barrier layer. Hence, the dopant distribution within a barrier layer of the subset or not of the subset may vary. For example, the dopants may be concentrated closer to or adjacent to a quantum well layer.

In some further aspects, the dopant concentration within the subset of the plurality of barrier layers is in the range between 2e17 1/cm³ to 5e18 1/cm³. While they are generally below 1e19 1/cm³, the dopant concentration within the subset may be at least twice as large as dopant concentration in the remaining barrier layers not part of the subset. In an alternative embodiment, the dopant concentration within the subset may be at least twice as large as average dopant concentration within the active region. In some aspects, an average dopant concentration within the plurality of barrier layers is in the range between 1e17 1/cm³ and 1e18 1/cm³.

In some aspects, the optoelectronic device further comprises a Silicon dopant within the active region, said Silicon dopant comprising a different doping type.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows an embodiment of an optoelectronic device implementing some aspects of the proposed principle;

FIG. 2 illustrates a first embodiment of an active region implementing some aspects of the proposed principle;

FIG. 3 shows a second embodiment of an active region in accordance with some aspects of the proposed principle;

FIG. 4 illustrates a third embodiment of an active region in accordance with some aspects of the proposed principle;

FIG. 5 shows a fourth embodiment of an active region implementing some aspects of the proposed principle;

FIG. 6 illustrates a fifth embodiment of an active region implementing some further aspects of the proposed principle;

FIG. 7 shows another embodiment of an active region to illustrate some aspects of the proposed principle;

FIG. 8 shows a diagram of dopant concentration across an active region in accordance with some aspects of the proposed principle; and

FIG. 9 illustrates a diagram representing the deviation of the forward voltage of an optoelectronic device in relation to a relative doping concentration within the active region.

### DETAILED DESCRIPTION OF ILLUSTRATIVE EMBODIMENTS

The following embodiments and examples disclose various aspects and their combinations according to the proposed principle. The embodiments and examples are not always to scale. In particularly, although the expression optoelectronic device is used throughout the present application, it is not limited to large devices. In particular the expression shall encompass so called μ-LEDs, which generally comprise smaller dimensions less than 3000 μm² and even less than 1000 μm² or a length down to a few μm. Likewise, different elements can be displayed enlarged or reduced in size to emphasize individual aspects. It goes without saying that the individual aspects of the embodiments and examples shown in the figures can be combined with each other without further ado, without this contradicting the principle according to embodiments of the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

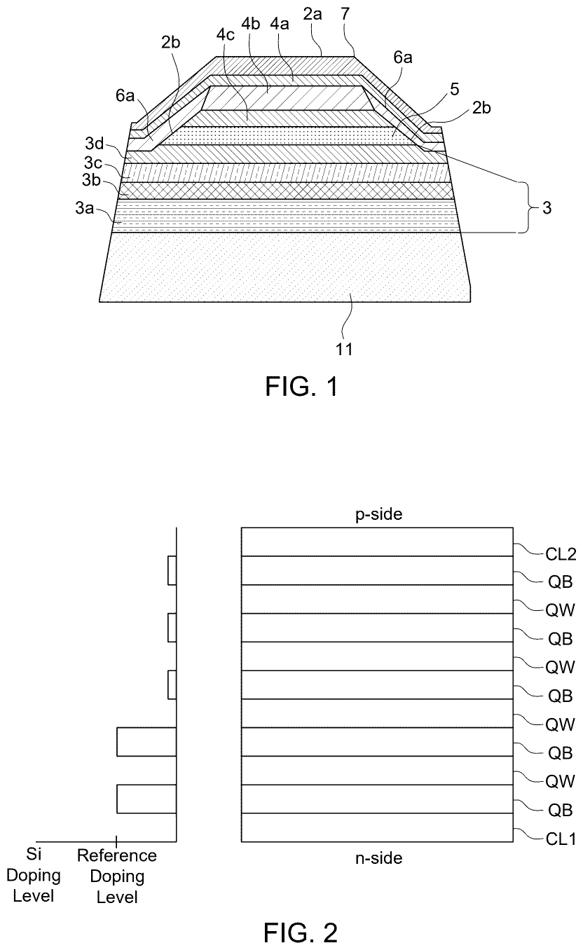

FIG. 1 shows a cross section of an optoelectronic device configured as a single μLED that implements an improved active region in accordance with the proposed principle. The optoelectronic device 1 includes layer stack 2, in particular a semiconductor layer stack based on a nitride material system deposited on a temporary carrier substrate 11. More particularly, the layer stack 2 deposited on the carrier substrate comprises a first charge carrier transportation layer 3 of a first doping type, a second charge carrier transportation layer 4 of a second doping type, an active region 5 arranged between the first and second charge carrier transportation layer.

In the present embodiment, the layer stack includes a top surface 2a as well as inclined side surfaces 2b adjacent to the top surface, wherein the side surfaces are inclined with respect to a normal N of the top surface 2a with the angle α. The angle α can be based on the etching process as discussed below, but also depend on the crystal direction of the material used. The angle can also vary along the sidewall with various angles being possible.

Referring now to the layer stack 2 in greater detail, the stack comprises a first charge carrier transportation layer corresponding to a first layer of a first doping type. As illustrated in FIG. 1, the first layer 3 comprise one or several n-doped sublayers 3b to 3d deposited on buffer layer 3a. Buffer layer 3a is adjacent to the carrier layer 11. Carrier layer 11 may comprise Al₂O₃ for example, on which a buffer layer of n-doped GaN or AlGaN layer 3a and subsequently layers 3b, 3c and 3d are deposited. Buffer layer 3a may later be removed.

Several doped and/or undoped sublayers 3b, 3c and 3d are provided on top of layer 3a, acting as charge distribution layer, charge transportation layer or providing other and different functionalities. Sublayer 3d comprises InGaAlN for example and is located directly adjacent to active region 5. The layer 3d is undoped and may comprise only a thickness of a few ios of nm. It acts as a cladding layer to the active region and prevents undesired diffusion of dopants from sublayers 3b and 3c into the active region 5.

Active region 5 comprises a multi quantum well structure, which will be explained later on in greater detail. A similar cladding layer 4c is subsequently provided on top of active region 5, where cladding layer 4c forms a sub-layer of the second charge carrier transportation layer 4. Similar to the first layer 3, second charge carrier transportation layer 4 comprises several p-doped layers 4a, 4b, respectively, as well as one or several undoped barrier layers 4c adjacent to the active region 5. Both layers 3d and 4c may comprise the same or a very similar composition material with regards to the active layer 5. In the given example both comprise undoped InGaAlN material.

The optoelectronic device 1 further comprises inclined sidewalls starting from the first charge transportation layer 3, more particularly sublayer 3d up to about the sublayer 4b being part of the second charge carrier transportation layer (being p-doped). The area of the top sub-layer 4b is smaller than the other sub-layers 4c, the active region 5 and/or the first charge carrier transportation layer. In other words, the inclined surface with angle α to the normal N is smaller than 90°.

The sidewalls 2b of the layer stack are covered by layer 6a, which is overgrown during processing the device and leaving at least portions of the top surface 2a exposed. The material of layer 6a is chosen to provide a larger bandgap than the active region 5, but optionally also of the adjacent layers 4c, 4b, and 3d of the first and second charge transportation layer. In some aspects, layer 6a can be an insulating layer. The larger bandgap of layer 6a causes an electrical barrier preventing charge carriers injected into the active region from diffusing to the side wall and recombining in a non-radiative manner. While this aspect may not be of high relevance here due to the material system and its short diffusion length, layer 6a nevertheless protects the layer stack underneath from oxygen, dirt or possible damage.

Material of a highly p-doped contact sublayer 4a is deposited on top of the overgrown insulating layer 6a and sublayer 4b, contact sublayer 4a forming a part of the second charge carrier transportation layer 4. Finally, a metallic contact 7 is applied onto sublayer 4a. The present structure can be varied, in particularly the material on the insulating layer 2b on the sidewalls can be removed or the insulating material protected from being overgrown by sublayer 4a.

The present structure can be processed by providing the carrier substrate ni and then depositing the respective layers stacks. First the buffer layer 3a is deposited in such way that a smooth and preferably defect-free or defect reduced surface is established. Said surface is used to deposit further sublayers of the first layer 3, those sublayers being n-doped except for the cladding sublayer 3d. the semiconductor material used for the sub layers can vary depending on the desired functionality, but usually includes one or more layers of InGaN or InGaAlN material with varying Al content. A typical material for the doping is Silicon, which acts as an n-dopant for the InGaN/InGaAlN based material system.

Then, a multi quantum well structure in active region 5 is deposited as explained further down below in greater detail. A further undoped cladding sublayer layer 4c is deposited on the finished active region followed by a p-doped charge carrier transportation layer. in a next step a structured hard mask is applied with exposing surface regions of layer 4b. Those exposed surface regions are etched to form the mesa structure as depicted in FIG. 1. The exposed side edges of the mesa structure are covered by material of layer 6a and the remaining portions of the hard mask is removed. Then, the remaining sublayers of second layer 4 are deposited.

A plurality of various embodiments can be implemented for the processing method in accordance with the proposed principle, the one presently indicated being a non-limiting example.

Referring now to the deposition of the active region, its structure as well as its characteristics. To operate the optoelectronic device or μLED illustrated in FIG. 1, the charges in this active region and more particularly in the depleted portion thereof must be removed by pushing free carriers into the depletion region. This process happens when the device is turned on as well as when it is turned off. Hence, a portion of the charge carriers is used to de-populate or re-populate the active region and will therefore not participate in any light generation. The resulting capacitance in the pn-junction,—that is the active region—is dependent on the amount of such carriers, which can be varied by doping the active region with Silicon or Magnesia for example. To reduce the overall capacitance of the pn-junction, one can reduce the amount of dopants within the active region resulting in a higher switching speed.

The proposed principle aims to minimize the capacitance within the region without sacrificing the reduced threshold voltage U_{f} induced by the doping in the active region. The overall capacitance within the active region corresponds to C=Q/V where Q are the available charge carriers within the region and given by

$$Δ Q ∼ \sqrt{\frac{{n}_{A} * {n}_{D}}{( {n}_{A} + {n}_{D} )}}$$

whereas n_{A} and n_{D} are the donor and acceptor concentration, respectively. For the present material system Magnesia Mg is used as acceptor (p-dopant), and Silicon is used as donor (n-dopant). Reducing the charge ΔQ is achievable by either reducing the donor and/or the acceptor concentration.

FIG. 9 illustrates the space charges at 0V as a function of Si doping, showing a squarer root dependence on integrated Si doping. Integrated Si doing corresponds to the average Si doping concentration. As visible with higher Si dopant concentration e.g. close to 100% as reference level, one can observe an increasing charge voltage up to 1.8V. the curve itself follows a square root dependence. On the other hand, a smaller average Si doping results in an increase of the operating voltage. The table below illustrates the change of the forward voltage ΔU_{f} and the quantum efficiency Ie with regards to a reference of an 80% average doping level.

| | aver. Si | ΔUf | Ie % |
|---|---|---|---|
| 1 | 80.0% | Reference | 100.0% |
| 2 | 40.0% | +20 mV | 100.7% |
| 3 | 30.4% | +35 mV | 101.3% |
| 4 | 25.0% | +45 mV | 101.0% |
| 5 | 20.0% | +85 mV | 99.2% |

With a reduced amount of Si doping, e.g. appr. half the reference level, the forward voltage U_{f} already increases by 20 mV further increasing with decreasing Silicon doping concentration across the active region. Although the quantum efficiency may slightly increase (may be due to a reduced number of non-radiating recombination centres, the increase forward voltage U_{f} results in some disadvantages.

As a result thereof, a revised doping scheme within the active region and more particularly within the barrier layers of the multi quantum well structure of the active region is proposed.

FIGS. 2 to 5 illustrate various embodiments of a multi-quantum well structure in accordance with the proposed principle having a plurality of alternating quantum well layers and quantum barrier layers, respectively, as well as an adjusted doping distribution within the quantum barrier layers.

The doping distribution is considered from a reference doping level which is used in conventional devices corresponding to the reference level of 100% Silicon dopant concentration as illustrated in table 1 above. Such dopant level results in a certain quantum efficiency, but also in a specific forward voltage, which is lower compared to a non-doped active region.

In the respective embodiments of FIGS. 2 to 5 various principles and options for different doping levels are illustrated resulting in a reduced capacitance in the active region and similar forward voltages U_{f}, although the precise amount and the precise reduction of the overall Silicon doping concentration within the active region may vary and dependent on the actual implementation.

In particular as outlined further below, the overall Silicone concentration is about 30% of the reference level given in table 1. When considering conventional devices, the reduction results in a decrease of the average Silicon level to about 30%, but its distribution is substantially equal across the active region. As shown in table 1, such approach results in a substantial increase of the forward voltage U_{f}.

However, in the proposed embodiments, the voltage level can be substantially maintained at the reference level comparable to the 80% of average doped Silicon as outlined in table 1, while at the same time increasing the quantum efficiency and reducing the overall capacitance.

As a result of the reduced average Silicon dopant concentration, the capacitance is reduced, leading to increased switching speed while maintaining the same forward voltage U_{f} as in conventional devices with a hundred percent reference level of the Silicon doping. In addition to the increased switching speed, the quantum efficiency may slightly increase due to the reduced concentration of non-radiative recombination centres.

The right sides of each embodiment (FIGS. 2 to 5) show an active region with a plurality of quantum barrier layers QB and quantum well layers QW stacked on top of each other between a cladding layer CL1 and CL2, respectively. The cladding layer CL1 and CL2 are undoped and comprise a ternary or quaternary nitride-based material system. Such system includes InGaAlN, but it is not limited to such example.

In this regard, the cladding layers Cl1 and Cl2 of the embodiments comprise a thickness of a few nanometres and act as diffusion barrier to prevent dopants from the adjacent carrier transportation layers, (not shown herein) into the active region and the quantum barrier layers, respectively or vice versa. Each quantum barrier layer QB comprises an aluminum content, which is larger than an aluminum content of the adjacent quantum well layer and the cladding layers CL1 and CL2, respectively. In particular, the aluminum content for quantum barrier layer QB within the active region may range from 0% to 40% for blue or other coloured LEDs, even in the layers used for electron blocking in p-side of the LED. For LEDS in the UV range, the Al content may be higher and can lie for example, in the range between 40% and 80%, respectively. Consequently, the semiconductor material for the quantum barrier layers QB can be Inₓ(Ga_{y}Al_{1-y})₁₋ₓN with 0.5<y<1 although even lower values of y are possible.

The quantum barrier layers QB comprise a thickness of a few of tens of nanometres, for example within the range between 5 nm and 50 nm, respectively. The quantum well layers QW have a similar thickness but comprise a lower level of aluminum, and in some instances, no aluminum at all (e.g. InₓGa₁₋ₓN only). By adjusting the Indium content of the quantum well layers, one can change the colour of the respective optoelectronic device. However, changing the Indium content may induce some strain within the crystal structure and should therefore be avoided or at least kept below a certain threshold.

The Silicon doping level with regards to a reference doping level for the quantum barrier layers are illustrated on the left side of the respective embodiments presented in FIGS. 2 to 5. Although in the present case, no Silicon doping is present in the respective quantum well layers QW, one should note that by diffusion or other means, Silicon atoms can diffuse into the quantum well layers QW. However, for the purpose of the proposed principle, no intentional Silicon doping within the quantum well layers QW are performed.

FIG. 2 illustrates a first embodiment, in which the first two quantum barrier layers, as seen from the n-doped side are doped with a Silicon doping level comparable to the reference doping level. The remaining three quantum barrier layers QB in the present embodiments are doped with a significant lower doping level compared to the reference doping level such that the overall average Silicon dopant concentration across the active region is approximately 30% of the reference level.

In the present case, a subset of the quantum barrier layers QB comprises a significantly higher Si dopant concentration than the remaining quantum barrier layers. The distribution of the Silicon doping within the active region is biased towards the n-doped side (with cladding layer CL1) within the corresponding quantum barrier layers. It has been found that such bias in the Silicon dopant concentration towards the n-doped side maintains the forward voltage level U_{f} compared to the Silicon doping reference level across all quantum barrier layers mentioned earlier. However, in accordance with the proposed principle, the overall silicon dopant concentration (or the amount of Si in the active region) is about 30% of the reference level thereby reducing the capacitance in the active region significantly. The quantum well layers remain substantially undoped, i.e. they have not been intentionally doped with Silicon.

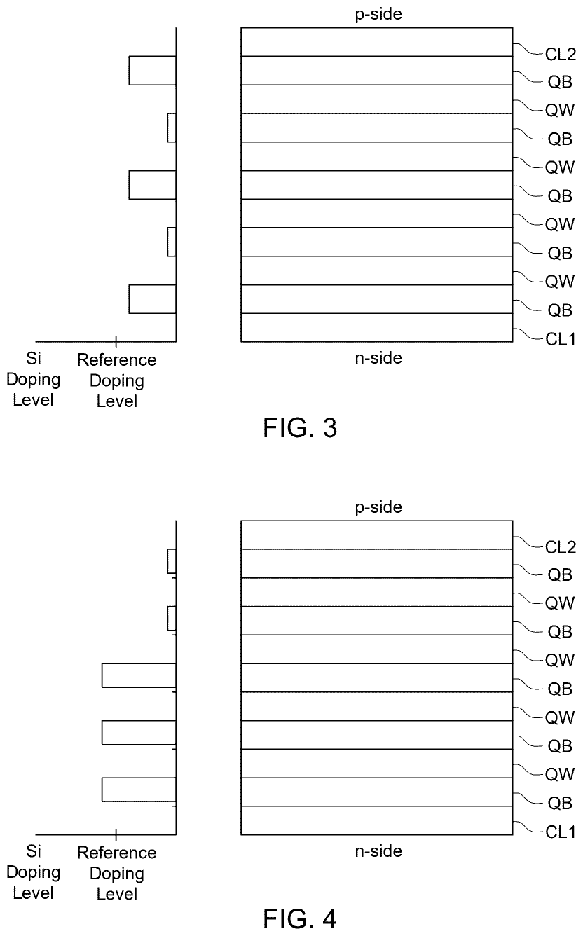

FIG. 3 illustrates a further embodiment of an active region and the corresponding levels of Silicon dopant in the quantum barrier layers QB. In this embodiment, only each second quantum barrier layer contains a larger Silicon dopant concentration. More particularly, the quantum barrier layers QB adjacent to the cladding layers CL1 and CL2 comprise a higher Silicon dopant concentration compared to their neighbouring quantum barrier layers. More particular in some aspects, the Silicon doping of each second quantum barrier layer QB can be set to lower values or even 0, whereas almost no Silicon doping takes place during the deposition of the material of the quantum barrier layer QB. Similar to the previous embodiment, the overall level of Silicon dopants is approximately 30% compared to the reference level.

In this particular embodiment, alternating quantum barrier layers are doped with a larger amount of Silicon, although even for those higher doped barrier levels, the dopant concentration is slightly below the reference level. Still, the low forward voltage U_{f} is maintained and the overall active region capacitance reduced due to the overall lower amount of Silicon in the quantum barrier layers

In some other alternative embodiments, the distribution of dopant concentration is reversed, that is, in contrast to the embodiment of FIG. 3, the quantum barrier layers adjacent to the cladding layers may be doped with a smaller concentration of Silicon to avoid diffusion of the Silicon material into the cladding layer. Furthermore, the dopant concentration within the higher doped quantum barrier layers may additionally be adjusted to different levels.

In a further embodiment illustrated in FIG. 4, the distribution of Silicon atoms deposited during deposition of the respective quantum barrier layers are not constant. In the present embodiment, the active region again comprises a plurality of alternating quantum barrier layers QB and quantum well layers QW, respectively. In the embodiment, the Silicon dopant concentration in the quantum barrier layer QB is not constant, but biased and shifted towards the adjacent quantum well layer when viewed from the n-side. More particularly, during deposition of the quantum barrier layer, a short portion of the quantum barrier layer material is deposited without additional Silicon doping. After a few nanometres of depositing quantum barrier layer material, the Silicon dopant is added resulting in a doped deposition of quantum barrier layer material. The Silicon doping continues until the deposition of the barrier layer material is finalized and the deposition of the quantum well layer material is initiated.

As a result illustrated on the left side of the embodiment of FIG. 4, the concentration of Silicon dopants at each initial starting position of a quantum barrier layer is substantially zero or at least very low, but jumps after a short distance within the quantum barrier layer to a level slightly above the reference level.

In addition, the overall deposition of Silicon is not equal, but similar to the embodiment of FIG. 2, only the first few quantum barrier layers are heavily doped with Silicon dopants. In the present embodiment, the first three quantum barrier layers when viewed from the n-doped side of the device are heavily doped in a respective sub-portion of the quantum barrier layer. The remaining two quantum barrier layers closer to the p-side are doped with Silicon as well but with a smaller concentration during its respective deposition. More particularly, the heavily doped quantum barrier layers comprise Silicon concentration that might be even above the average reference level as indicated on the left side of FIG. 4. However, the overall Silicon dopant concentration in the quantum barrier layers is approximately about 30% compared to the reference level.

The present embodiment about two thirds of the thickness of each quantum barrier layer is doped with Silicon, while the remaining one third of its thickness adjacent to a quantum well layer or the cladding layer CL1 remains undoped. On the other hand, the higher Silicon doped side continues to the adjacent quantum well layer or to the second cladding layer CL2. In other words, some of the quantum well layers are located adjacent to a quantum barrier layer with a high doping concentration directly adjacent and a second quantum barrier layer with a lower doping concentration, respectively. Depending on the diffusion characteristics of Silicon within the quantum barrier layer, the resulting structure may slightly decompose resulting in a different dopant distribution compared to the illustration in FIG. 4.

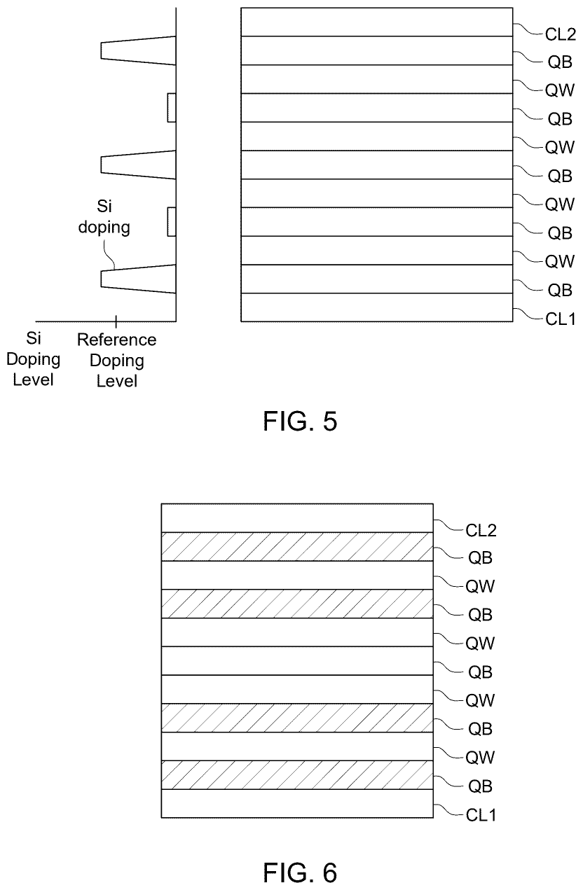

In some further instances, the dopant concentration can be varied continuously throughout the deposition of the quantum barrier layer material starting from a low level and increasing to a high level above or below the respective reference level. Such an embodiment is illustrated in FIG. 5.

In this embodiment, the first, third and fifth quantum barrier layer QB are doped with a Silicon concentration starting from a relatively low level and continuously increasing to a higher level at approximately half of the thickness of the respective quantum barrier layer. During deposition of the respective quantum barrier layer material, the Silicon dopant concentration is continuously increased until it reaches its upper limit to remain constant for the remaining deposition of the barrier layer. As a result, the Silicon doping concentration starts from a low level and increases constantly above the reference level to be constant across a certain thickness of the first, third and fifth quantum barrier layer. The second and fourth quantum barrier layers are either substantially un-doped or at least doped with a concentration 20% or lower than the reference level. Similar to the previous embodiment, the overall dopant concentration of Silicon in the active region is approximately one third of the reference level.

FIG. 6 illustrates yet another embodiment in which one or more quantum barrier layers centrally arranged within the active region are left undoped, while the quantum barrier layers adjacent to the cladding layers Cl1 and Cl2 are doped with Silicon at a higher concentration. Hence, in the present embodiment, the quantum barrier layers QB with the higher doping scheme are front- and rear-biased while the centrally arranged quantum barrier layers are undoped. Of course that structure can be reversed with the quantum barrier layers adjacent or close to both cladding layers are undoped and the centrally arranged quantum barrier layers are doped with a higher level of Silicon concentration. This may be useful to prevent dopants from diffusion through the cladding layers and the adjacent barrier layers into the quantum well layers.

Although in the present embodiments of FIGS. 2 to 6, only five quantum barrier layers and quantum well layers, respectively are illustrated for the active region, it is possible for the skilled person to implement a plurality of such barrier and quantum well layers without being limited to the specific numbers illustrated herein.

However, in accordance with embodiments of the present invention, a subset of quantum barrier layers comprises a higher Silicon dopant concentration than the remaining quantum barrier layers, although the numbers of the barrier layers corresponding to the subset is smaller than the number of barrier layers not corresponding to the subset.

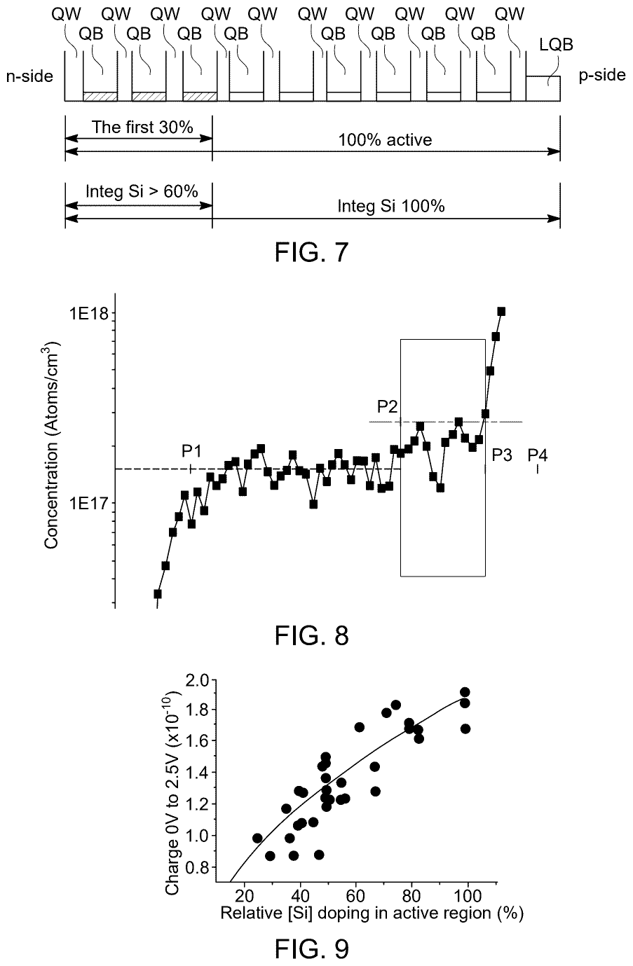

FIG. 7 illustrates an embodiment, in which a subset of quantum barrier layers QB staggered on the n-doped side of the active region comprises a higher dopant concentration. In this embodiment, the thickness of the quantum well layers QW are slightly smaller than those of the corresponding quantum barrier layers, although these thicknesses can be adjusted in accordance with the need of the respective device. Only approximately ⅓ of the quantum barrier layers QB are actually doped with a larger amount of Silicon, whereas the remaining quantum barrier layers comprise a significantly lower Silicon concentration. The overall concentration of Silicon lies between 20% to 30% of the previously mentioned reference level.

The two diagrams below the structure of FIG. 7 illustrate this aspect in greater detail. In particularly, the highly doped Silicon layer are front-biased when viewed from the n-doped side of the device, whereas only the first 30% of quantum barrier layers comprise a higher Silicon doping, while the remaining 70% of quantum barrier layers comprise a significantly lower Silicon dopant concentration. On the other hand approximately 60%, 70% or even 80% of the overall amount of Silicon dopants are concentrated within those 30% of quantum barrier layers. In other words, more than 60% of all Silicon is generally located within the first 30% of the overall thickness of the active region.

The remaining 20% to 40% of Silicon dopants are distributed across of the remaining quantum barriers QB as shown in FIG. 7. However, the overall amount of Silicon dopant is reduced with regards to a reference level while maintaining the forward voltage and reducing the overall capacitance. The maintenance of the forward voltage U_{f} in comparison to the higher reference level of Silicon dopants in conventional devices is achieved by an unequal distribution of Silicon dopant concentration within the respective barrier layers.

In this regard, it has been found that doping the first few quantum barrier layers when viewed from the n-side with a higher dopant concentration may result not only in maintaining the reference voltage U_{f} but actually slightly decreasing the reference voltage, while at the same time also reducing the active region capacitance. An implementation of an active region with quantum barrier layers including a higher Silicon dopant concentration adjacent to the p-doped side may result in a forward voltage U_{f} close to the reference voltage, although, the overall Silicon the dopant concentration is approximately ⅓ to ½ of the reference concentration.

FIG. 8 shows a SIMS diagram of such dopant concentration for Silicon across an active region. Left from the indicated point P1, corresponding to the start of the active region at the p-doped side of an optoelectronic device, the Silicon concentration is below 1e17 1/cm³. Such value is close to the measurement limit for Silicon as a dopant. Between the points P1 and P2, that is within the active region, the dopant concentration in the respective barrier layers is substantially the same and about 1.5e17 1/cm³ to 2e17 1/cm³.

In the last section between points P2 and P3 in which quantum barrier layers with increased dopant concentration are implemented, one can observe an increase of the average dopant concentration to approximately 3e17 1/cm³ to 4e17 1/cm³. The dopant concentration will further increase from point P3 to a dopant concentration of about 1e18 1/cm³ at about point P4 corresponding to the n-doped side of the carrier transportation layer.

As described in the previous embodiments, a Silicon doping in the active region of an optoelectronic device can cause a significant decrease of the forward voltage and current. However, due to the biasing of the dopant within the active region, the overall amount of Silicon doping can be reduced while maintaining the forward voltage U_{f} at approximately the same level. The reduction of Silicon also reduces the capacitance and thus improves the switching speed. Therefore, a reduced capacitance and voltage can be obtained by adjusting different doping ratios across the active region.

1.-14. (canceled)

15. A method for manufacturing an optoelectronic device, the method comprising:
depositing a first layer having a first dopant concentration of a first doping type;
depositing an active region on the first layer; and
depositing a second layer having a second dopant concentration of a second doping type on the active region,
wherein depositing the active region comprises:
depositing a plurality of alternating barrier layers comprising Inₓ(Ga_{y}Al_{1-y})₁₋ₓN and quantum well layer comprising Inₓ(Ga_{y}Al_{1-y})₁₋ₓN, with x, y as parameters in an interval of [0;1], respectively and x+y=1, wherein an aluminum content in a barrier layer is higher than in a quantum well layer, and
doping the barrier layers with silicon during deposition of a barrier layer material such that a subset of the plurality of barrier layers comprises a higher silicon dopant concentration than remaining barrier layers, wherein the barrier layers of the subset and the remaining barrier layers are alternatingly arranged.

16. The method according to claim 15, wherein doping the barrier layers comprises doping the plurality of barrier layers during respective deposition of the barrier layer material, and wherein a dopant concentration is increased during deposition of the subset of the plurality of barrier layers.

17. The method according to claim 15, wherein an amount of barrier layers in the subset of the plurality of barrier layers is 15% to 45% of an overall amount of the plurality of barrier layers.

18. The method according to claim 15, wherein a dopant concentration in the subset of the plurality of barrier layers is larger than 50% of an overall dopant concentration in the plurality of barrier layers.

19. The method according to claim 15, wherein doping the barrier layers during the deposition of the barrier layer material comprises depositing a dopant material after depositing a portion of the respective barrier layer and/or finishing depositing a dopant material while continuing depositing the barrier layer material.

20. The method according to claim 15,
wherein a dopant concentration within the subset of the plurality of barrier layers is in a range between 2e17 1/cm³ to 5e18 1/cm³, and/or
wherein an average dopant concentration within the plurality of barrier layers is in a range between 1e17 1/cm³ and 1e18 1/cm³, inclusive, and/or
wherein a dopant concentration within the subset of the plurality of barrier layers is at least twice an average dopant concentration across the active region.

21. The method according to claim 15, further comprising doping at least portions of the active region with a dopant different from silicon.

22. An optoelectronic device comprising:
a first layer having a first dopant concentration of a first doping type;
an active region on the first layer; and
a second layer on the active region, the second layer having a second dopant concentration of a second doping type,
wherein the active region comprises a plurality of alternating barrier layers comprising Inₓ(Ga_{y}Al_{1-y})₁₋ₓN and quantum well layer comprising Inₓ(Ga_{y}Al_{1-y})₁₋ₓN, with x, y as parameters in an interval of [0:1], respectively and x+y=1, an aluminum content in a barrier layer being higher than an aluminum content in a quantum well layer,
wherein a subset of the plurality of barrier layers comprises a higher doping concentration than remaining barrier layers, and
wherein the barrier layers of the subset and the remaining barrier layers are alternatingly arranged.

23. The optoelectronic device according to claim 22,
wherein a number of barrier layers corresponding to the subset of barrier layers is smaller than a number of barrier layers not corresponding to the subset of barrier layers, and/or
wherein an amount of barrier layers in the subset of the plurality of barrier layers is 15% to 45% of an overall amount of the plurality of barrier layers.

24. The optoelectronic device according to claim 22,
wherein a thickness of a barrier layer of the subset of barrier layers is larger than a thickness of a doped region within the barrier layer, and
wherein optionally the doped region is not adjacent to quantum well layer adjacent to the barrier layer.

25. The optoelectronic device according to claim 22, wherein a dopant concentration in the subset of the plurality of barrier layers is larger than 55% of an overall dopant concentration in the plurality of barrier layers.

26. The optoelectronic device according to claim 22, wherein a dopant concentration in a barrier layer of the subset of the plurality of barrier layers varies along a thickness of the barrier layer.

27. The optoelectronic device according to claim 22,
wherein a dopant concentration within the subset of the plurality of barrier layers is in a range between 2e17 1/cm³ to 5e18 1/cm³, inclusive, and/or
wherein an average dopant concentration within the plurality of barrier layers is in a range between 1e17 1/cm³ and 1e18 1/cm³, inclusive, and/or
wherein a dopant concentration within the subset of the plurality of barrier layers is at least twice an average dopant concentration across the active region.

28. The optoelectronic device according to claim 22, further comprising a dopant within the active region, the dopant being different from silicon.
